(19) United States
(12) Patent Application Publication
(10) Pub. No.: US 2023/0005972 A1
(43) Pub. Date: Jan. 5, 2023

(54) BACKSIDE ILLUMINATED IMAGE SENSOR AND METHOD OF MANUFACTURING THE SAME

(71) Applicant: DB HITEK CO., LTD., Seoul (KR)

(72) Inventor: Tae Wook KANG, Gyeonggi-do (KR)

(21) Appl. No.: 17/809,986

(22) Filed: Jun. 30, 2022

(30) Foreign Application Priority Data
Jul. 2, 2021 (KR) 10-2021-0087278

(51) Int. Cl. H01L 27/146

(52) U.S. Cl. CPC H01L 27/1464; H01L 27/14636; H01L 27/14623; H01L 27/14621; H01L 27/14627; H01L 27/14685

(57) ABSTRACT

A backside illuminated image sensor includes a substrate having a frontside surface and a backside surface, a pixel region disposed in the substrate, a reinforcing pattern disposed on the frontside surface of the substrate, an insulating layer disposed on the frontside surface of the substrate and the reinforcing pattern, a bonding pad disposed on the insulating layer, and a second bonding pad electrically connected to the bonding pad through the substrate, the reinforcing pattern, and the insulating layer.

### CROSS-REFERENCE TO RELATED APPLICATION

This application claims the priority benefit of Korean Patent Application No. 10-2021-0087278, filed on Jul. 2, 2021, and all the benefits accruing therefrom under 35 U.S.C. § 119, the contents of which are incorporated by reference in their entirety.

### TECHNICAL FIELD

The present disclosure relates to a backside illuminated image sensor and a method of manufacturing the same. More specifically, the present disclosure relates to a backside illuminated image sensor including a color filter layer and a micro lens array formed on a backside surface of a substrate, and a method of manufacturing the same.

### BACKGROUND

In general, an image sensor is a semiconductor device that converts an optical image into electrical signals, and may be classified or categorized as a Charge Coupled Device (CCD) or a Complementary Metal Oxide Semiconductor (CMOS) Image Sensor (CIS).

The CIS includes unit pixels, each including a photodiode and MOS transistors. The CIS sequentially detects the electrical signals of the unit pixels using a switching method, thereby forming an image. The CIS may be classified as either a frontside illuminated image sensor or a backside illuminated image sensor.

The backside illuminated image sensor may include pixel regions formed in a substrate, transistors formed on a frontside surface of the substrate, an insulating layer formed on the transistors, bonding pads on the insulating layer, an anti-reflective layer formed on a backside surface of the substrate, a light-blocking pattern formed on the anti-reflective layer, a planarization layer formed on the light-blocking pattern, a color filter layer formed on the planarization layer, and a micro lens array formed on the color filter layer.

The bonding pads may be exposed by openings formed through the anti-reflective layer, the substrate and the insulating layer. Second bonding pads may be formed on the anti-reflective layer, inner side surfaces of the openings and the bonding pads exposed by the openings, and third bonding pads may be formed on the second bonding pads. Further, wires may be bonded on the third bonding pads or solder bumps may be formed on the third bonding pads. However, the second bonding pads may be peeled off from the bonding pads due to a difference in thermal expansion coefficient while performing the wire bonding process or forming the solder bumps.

### SUMMARY

The present disclosure provides a backside illuminated image sensor having an improved bonding pad structure and a method of manufacturing the backside illuminated image sensor.

In accordance with an aspect of the present disclosure, a backside illuminated image sensor may include a substrate having a frontside surface and a backside surface, a pixel region disposed in the substrate, a reinforcing pattern disposed on the frontside surface of the substrate, an insulating layer disposed on the frontside surface of the substrate and the reinforcing pattern, a bonding pad disposed on the insulating layer, and a second bonding pad electrically connected to the bonding pad through the substrate, the reinforcing pattern, and the insulating layer.

In accordance with some embodiments of the present disclosure, the backside illuminated image sensor may further include a field isolation region disposed in a frontside surface portion of the substrate. In such case, the reinforcing pattern may be disposed on a frontside surface of the field isolation region, and the second bonding pad may be electrically connected to the bonding pad through the field isolation region.

In accordance with some embodiments of the present disclosure, the substrate may have a first opening exposing a backside surface of the field isolation region, the field isolation region may have a second opening exposing a backside surface of the reinforcing pattern, the insulating layer may have at least one fourth opening exposing a backside surface of the bonding pad, and the reinforcing pattern may have at least one third opening connecting the second opening and the at least one fourth opening.

In accordance with some embodiments of the present disclosure, the reinforcing pattern may have a wider width than the second opening.

In accordance with some embodiments of the present disclosure, the reinforcing pattern may have a plurality of third openings having a slit shape and extending parallel to each other.

In accordance with some embodiments of the present disclosure, the reinforcing pattern may have a plurality of third openings arranged in rows and columns.

In accordance with some embodiments of the present disclosure, the backside illuminated image sensor may further include at least one gate structure disposed on the frontside surface of the substrate.

In accordance with some embodiments of the present disclosure, the at least one gate structure may include a gate insulating layer disposed on the frontside surface of the substrate, a gate electrode disposed on the gate insulating layer, and a gate spacer disposed on side surfaces of the gate electrode. In such case, the reinforcing pattern may be made of the same material as the gate electrode.

In accordance with some embodiments of the present disclosure, the backside illuminated image sensor may further include a second spacer disposed on side surfaces of the reinforcing pattern, and the second spacer may be made of the same material as the gate spacer.

In accordance with some embodiments of the present disclosure, the backside illuminated image sensor may further include an anti-reflective layer disposed on the backside surface of the substrate, and a light-blocking pattern disposed on the anti-reflective layer and having a fifth opening corresponding to the pixel region. In such case, the second bonding pad may be made of the same material as the light-blocking pattern.

In accordance with an aspect of the present disclosure, a method of manufacturing a backside illuminated image sensor may include forming a pixel region in a substrate, forming a reinforcing pattern on a frontside surface of the substrate, forming an insulating layer on the frontside surface of the substrate and the reinforcing pattern, forming a bonding pad on the insulating layer, and forming a second bonding pad to be electrically connected to the bonding pad through the substrate, the reinforcing pattern, and the insulating layer.

In accordance with some embodiments of the present disclosure, the method may further include forming a field isolation region in a frontside surface portion of the substrate. In such case, the reinforcing pattern may be formed on a frontside surface of the field isolation region, and the second bonding pad may be electrically connected to the bonding pad through the field isolation region.

In accordance with some embodiments of the present disclosure, the method may further include forming a first opening through the substrate to expose a backside surface of the field isolation region, forming a second opening through the field isolation region to expose a backside surface of the reinforcing pattern, and forming at least one third opening through the reinforcing pattern and at least one fourth opening through the insulating layer to expose a backside surface of the bonding pad.

In accordance with some embodiments of the present disclosure, the second bonding pad may be formed to fill the at least one third opening and the at least one fourth opening.

In accordance with some embodiments of the present disclosure, the first opening may partially expose the backside surface of the field isolation region, and the second opening may partially expose the backside surface of the reinforcing pattern.

In accordance with some embodiments of the present disclosure, the reinforcing pattern may be formed on the frontside surface of the field isolation region to have at least one through hole exposing a portion of the frontside surface of the field isolation region, and the at least one third opening and the at least one fourth opening may be formed by an anisotropic etching process using the reinforcing pattern as an etch mask.

In accordance with some embodiments of the present disclosure, the method may further include forming at least one gate structure on the frontside surface of the substrate.

In accordance with some embodiments of the present disclosure, the forming at least one gate structure may include forming a gate insulating layer on the frontside surface of the substrate, forming a gate electrode on the gate insulating layer, and forming a gate spacer on side surfaces of the gate electrode. In such case, the reinforcing pattern may be formed simultaneously with the gate electrode.

In accordance with some embodiments of the present disclosure, the method may further include forming a second spacer on side surfaces of the reinforcing pattern, and the second spacer may be formed simultaneously with the gate spacer.

In accordance with some embodiments of the present disclosure, the method may further include forming an anti-reflective layer on the backside surface of the substrate, and forming a light-blocking pattern having a fifth opening corresponding to the pixel region on the anti-reflective layer. In such case, the second bonding pad may be formed simultaneously with the light-blocking pattern.

In accordance with the embodiments of the present disclosure as described above, the second bonding pad may be electrically connected to the bonding pad through the insulating layer and the reinforcing pattern formed on the frontside surface of the substrate, and thus the second bonding pad may be firmly supported by the reinforcing pattern. As a result, the problem that the second bonding pad is peeled off from the bonding pad may be sufficiently solved.

The above summary of the present disclosure is not intended to describe each illustrated embodiment or every implementation of the present disclosure. The detailed description and claims that follow more particularly exemplify these embodiments.

### BRIEF DESCRIPTION OF THE DRAWINGS

Embodiments can be understood in more detail from the following description taken in conjunction with the accompanying drawings, in which:

FIG. 1 is a schematic cross-sectional view illustrating a backside illuminated image sensor in accordance with an embodiment of the present disclosure;

FIG. 2 is a schematic plan view illustrating a reinforcing pattern as shown in FIG. 1;

FIG. 3 is a schematic plan view illustrating another example of the reinforcing pattern as shown in FIG. 1;

FIG. 4 is a schematic plan view illustrating still another example of the reinforcing pattern as shown in FIG. 1; and

FIGS. 5 to 16 are schematic cross-sectional views illustrating a method of manufacturing the backside illuminated image sensor as shown in FIG. 1.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION

Hereinafter, embodiments of the present invention are described in more detail with reference to the accompanying drawings. However, the present invention is not limited to the embodiments described below and is implemented in various other forms. Embodiments below are not provided to fully complete the present invention but rather are provided to fully convey the range of the present invention to those skilled in the art.

In the specification, when one component is referred to as being on or connected to another component or layer, it can be directly on or connected to the other component or layer, or an intervening component or layer may also be present. Unlike this, it will be understood that when one component is referred to as directly being on or directly connected to another component or layer, it means that no intervening component is present. Also, though terms like a first, a second, and a third are used to describe various regions and layers in various embodiments of the present invention, the regions and the layers are not limited to these terms.

Terminologies used below are used to merely describe specific embodiments, but do not limit the present invention. Additionally, unless otherwise defined here, all the terms including technical or scientific terms, may have the same meaning that is generally understood by those skilled in the art.

Embodiments of the present invention are described with reference to schematic drawings of ideal embodiments. Accordingly, changes in manufacturing methods and/or allowable errors may be expected from the forms of the drawings. Accordingly, embodiments of the present invention are not described being limited to the specific forms or areas in the drawings and include the deviations of the forms. The areas may be entirely schematic, and their forms may not describe or depict accurate forms or structures in any given area, and are not intended to limit the scope of the present invention.

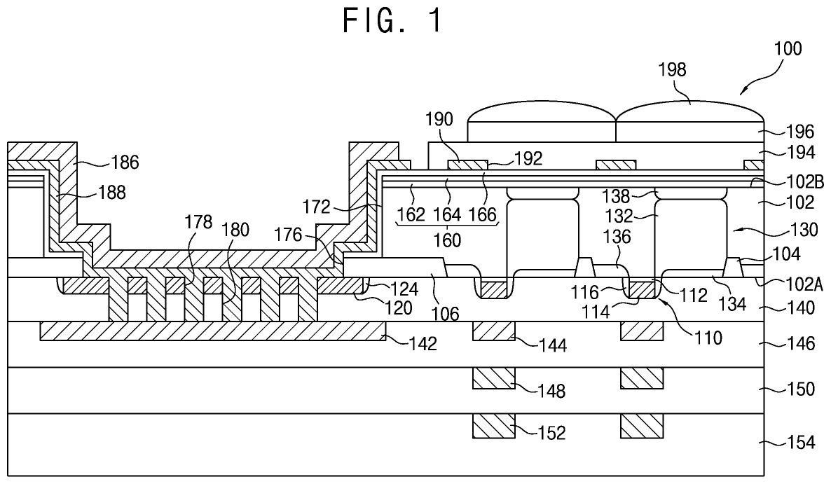

FIG. 1 is a schematic cross-sectional view illustrating a backside illuminated image sensor in accordance with an embodiment of the present disclosure.

Referring to FIG. 1, a backside illuminated image sensor 100, in accordance with an embodiment of the present disclosure, may include a substrate 102 in which pixel regions 130 are formed, a reinforcing pattern 120 formed on a frontside surface 102A of the substrate 102, an insulating layer 140 formed on the frontside surface 102A of the substrate 102 and the reinforcing pattern 120, a bonding pad 142 formed on a frontside surface of the insulating layer 140, and a second bonding pad 188 electrically connected to a backside surface of the bonding pad 142 through the substrate 102, the reinforcing pattern 120, and the insulating layer 140.

Further, the backside illuminated image sensor 100 may include a field isolation region 106 formed in a frontside surface portion of the substrate 102. In this case, the reinforcing pattern 120 may be formed on a frontside surface of the field isolation region 106, and the second bonding pad 188 may pass through the field isolation region 106 to be electrically connected to the backside surface of the bonding pad 142. That is, the second bonding pad 188 may pass through the substrate 102, the field isolation region 106, the reinforcing pattern 120, and the insulating layer 140 to be electrically connected to the backside surface of the bonding pad 142.

In accordance with an embodiment of the present disclosure, the substrate 102 may have a first opening 172 exposing a backside surface of the field isolation region 106, and the field isolation region 106 may have a second opening 176 exposing a backside surface of the reinforcing pattern 120. Further, the insulating layer 140 may have fourth openings 180 exposing the backside surface of the bonding pad 142, and the reinforcing pattern 120 may have third openings 178 connecting the second opening 176 and the fourth openings 180.

Each of the pixel regions 130 may include a charge accumulation region 132 in which charges generated by the incident light are accumulated. The charge accumulation regions 132 may be disposed in the substrate 102, and floating diffusion regions 136 may be disposed in frontside surface portions of the substrate 102 to be spaced apart from the charge accumulation regions 132. Further, device isolation regions 104 may be formed between the pixel regions 130.

The substrate 102 may have a first conductivity type, and the charge accumulation regions 132 and the floating diffusion regions 136 may have a second conductivity type. For example, a p-type substrate may be used as the substrate 102, and n-type impurity diffusion regions functioning as the charge accumulation regions 132 and the floating diffusion regions 136 may be formed in the p-type substrate 102. As another example, the substrate 102 may include a P-type epitaxial layer (not shown). In this case, the charge accumulation regions 132 and the floating diffusion regions 136 may be formed in the P-type epitaxial layer.

Transfer gate structures 110 may be disposed on channel regions between the charge accumulation regions 132 and the floating diffusion regions 136 to transfer the charges accumulated in the charge accumulation regions 132 to the floating diffusion regions 136. Each of the transfer gate structures 110 may include a gate insulating layer 112 disposed on the frontside surface 102A of the substrate 102, a gate electrode 114 disposed on the gate insulating layer 112, and a gate spacer 116 disposed on side surfaces of the gate electrode 114. Further, though not shown in FIG. 1, the backside illuminated image sensor 100 may include reset transistors, source follower transistors, and select transistors disposed on the frontside surface 102A of the substrate 102 and electrically connected with the floating diffusion regions 136.

In accordance with an embodiment of the present disclosure, the reinforcing pattern 120 may be made of the same material as the gate electrode 114. For example, the reinforcing pattern 120 and the gate electrode 114 may be simultaneously formed. Further, a second spacer 124 may be formed on side surfaces of the reinforcing pattern 120. For example, the second spacer 124 may be formed of the same material as the gate spacer 116 and may be simultaneously formed with the gate spacer 116.

Alternatively, if the backside illuminated image sensor 100 is a 3T (or fewer than three transistors) layout, the transfer gate structures 110 may be used as reset gate structures, and the floating diffusion regions 136 may be used as active regions for connecting the charge accumulation regions 132 with reset circuitries.

Each of the pixel regions 130 may include a frontside pinning layer 134 disposed between the frontside surface 102A of the substrate 102 and the charge accumulation region 132. Further, each of the pixel regions 130 may include a backside pinning layer 138 disposed between a backside surface 102B of the substrate 102 and the charge accumulation region 132. The frontside and backside pinning layers 134 and 138 may have the first conductivity type. For example, p-type impurity diffusion regions may be used as the frontside and backside pinning layers 134 and 138.

A first wiring layer 144 may be disposed on the insulating layer 140 and may be electrically connected with the pixel regions 130. At this time, the first wiring layer 144 may be made of the same material as the bonding pad 142. Further, a second insulating layer 146 may be disposed on a frontside surface of the insulating layer 140, the bonding pad 142 and the first wiring layer 144, and a second wiring layer 148 may be disposed on the second insulating layer 146. A third insulating layer 150 may be disposed on the second insulating layer 146 and the second wiring layer 148, and a third wiring layer 152 may be disposed on the third insulating layer 150. A passivation layer 154 may be disposed on the third insulating layer 150 and the third wiring layer 152.

An anti-reflective layer 160 may be formed on the backside surface 102B of the substrate 102, and a light-blocking pattern 190 having fifth openings 192 respectively corresponding to the pixel regions 130 may be formed on the anti-reflective layer 160. A planarization layer 194 made of an insulating material, for example, silicon oxide or a thermosetting resin, may be formed on the anti-reflective layer 160 and the light-blocking pattern 190. Further, a color filter layer 196 and a microlens array 198 may be sequentially formed on the planarization layer 194.

For example, the anti-reflective layer 160 may include a metal oxide layer 162 disposed on the backside surface 102B of the substrate 102 and silicon oxide layer 164 disposed on the metal oxide layer 162. The metal oxide layer 162 may function as a fixed charge layer. For example, the metal oxide layer 162 may function as a negative fixed charge layer and include hafnium oxide (HfO₂), hafnium oxynitride (HfON), aluminum oxide (Al₂O₃), aluminum oxynitride (AlON), hafnium aluminum oxide (HfAlO) or hafnium aluminum oxynitride (HfAlON). In such case, negative charges of the negative fixed charge layer may form a negatively charged shallow minority carrier rich region, i.e., a hole accumulation region, in a backside surface portion of the substrate 102, and the hole accumulation region may improve the function of the backside pinning layers 138. Particularly, a dark current of the backside illuminated image sensor 100 may be reduced. As an example, an aluminum oxide layer may be formed on the backside surface 102B of the substrate 102, a hafnium oxide layer may be formed on the aluminum oxide layer, and the silicon oxide layer 164 may be formed on the hafnium oxide layer.

Alternatively, when the charge accumulation region 132 has the first conductivity type, that is, an n-type substrate is used as the substrate 102 and the charge accumulation region 132 include p-type impurities, the metal oxide layer 162 may function as a positive fixed charge layer and include zirconium oxide (ZrO₂), hafnium silicon oxide (HfSiO₂), hafnium silicon oxynitride (HfSiON) or silicon nitride (Si₃N₄). In such case, the positive fixed charge layer may form an electron accumulation region in a backside surface portion of the substrate 102.

In accordance with an embodiment of the present disclosure, the anti-reflective layer 160 may further include a second silicon oxide layer 166 formed on the silicon oxide layer 164 and inner side surfaces of the first opening 172. The second silicon oxide layer 166 may be used to prevent contact between the substrate 102 and the second bonding pad 188.

The second bonding pad 188 may be made of the same material as the light-blocking pattern 190, and a third bonding pad 186 may be formed on the second bonding pad 188. Although not shown in FIG. 1, a wire may be bonded to the third bonding pad 186 through a wire bonding process, or a solder bump may be formed on the third bonding pad 186.

In accordance with an embodiment of the present disclosure, the reinforcing pattern 120 may have a wider width than the second opening 176. For example, as shown in FIG. 1, an edge portion of the reinforcing pattern 120 may be disposed between the field isolation region 106 and the insulating layer 140. Further, the second bonding pad 188 may be formed on the backside surface of the bonding pad 142 through the third openings 178 and the fourth openings 180. For example, the third openings 178 and the fourth openings 180 may be filled by the second bonding pad 188. As a result, a contact area between the second bonding pad 188, the reinforcing pattern 120 and the insulating layer 140 may be increased, and thus, the problem that the second bonding pad 188 is peeled off from the bonding pad 142 may be solved.

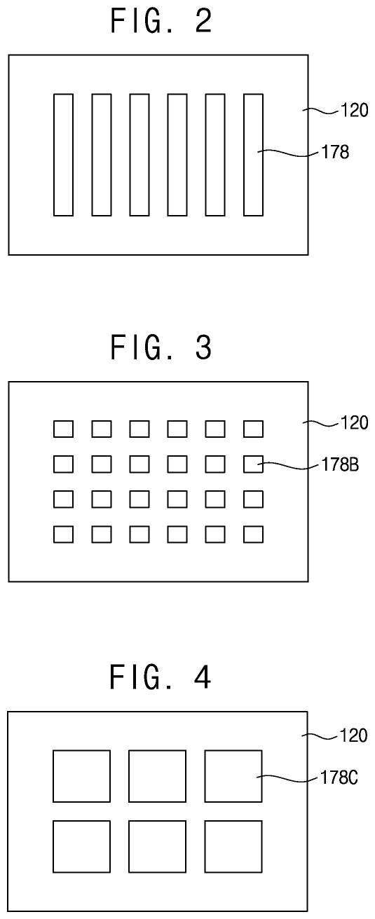

FIG. 2 is a schematic plan view illustrating a reinforcing pattern as shown in FIG. 1, FIG. 3 is a schematic plan view illustrating another example of the reinforcing pattern as shown in FIG. 1, and FIG. 4 is a schematic plan view illustrating still another example of the reinforcing pattern as shown in FIG. 1.

Referring to FIG. 2, the reinforcing pattern 120 may have a plurality of third openings 178 having a slit shape and extending parallel to each other. Further, as shown in FIG. 3, the reinforcing pattern 120 may have a plurality of third openings 178B having a rectangular shape and arranged in rows and columns. Still further, as shown in FIG. 4, when the reinforcing pattern 120 has third openings 178C having a relatively large size, the second bonding pad 188 may be formed along inner surfaces of the third openings 178C and the fourth openings 180.

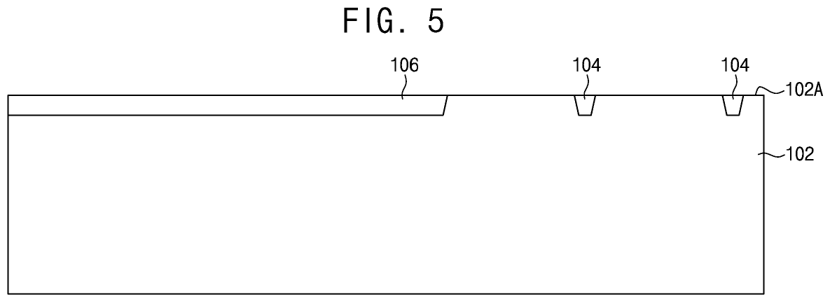

FIGS. 5 to 16 are schematic cross-sectional views illustrating a method of manufacturing the backside illuminated image sensor as shown in FIG. 1.

Referring to FIG. 5, device isolation regions 104 may be formed in frontside surface portions of a substrate 102 to define active regions of the backside illuminated image sensor 100. Further, a field isolation region 106 may be formed in a pad region of the substrate 102 together with the device isolation regions 104. For example, the substrate 102 may have a first conductivity type. For example, a p-type substrate may be used as the substrate 102. Alternatively, the substrate 102 may include a bulk silicon substrate and a p-type epitaxial layer formed on the bulk silicon substrate. The device isolation regions 104 and the field isolation region 106 may be made of silicon oxide and may be formed by a shallow trench isolation (STI) process.

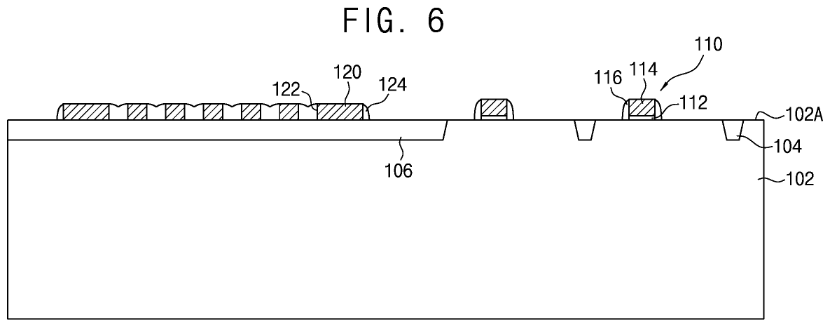

Referring FIG. 6, after forming the device isolation regions 104 and the field isolation region 106, transfer gate structures 110 may be formed on a frontside surface 102A of the substrate 102. Each of the transfer gate structures 110 may include a gate insulating layer 112, a gate electrode 114 formed on the gate insulating layer 112 and a gate spacer 116 formed on side surfaces of the gate electrode 114. Further, though not shown in figures, reset gate structures, source follower gate structures and select gate structures may be simultaneously formed with the transfer gate structures 110 on the frontside surface 102A of the substrate 102.

In accordance with an embodiment of the present disclosure, a reinforcing pattern 120 may be formed on a frontside surface of the field isolation region 106. The reinforcing pattern 120 may be formed simultaneously with the gate electrode 114. For example, after forming an impurity-doped polysilicon layer on the frontside surface 102A of the substrate 102, the gate electrode 114 and the reinforcing pattern 120 may be simultaneously formed by patterning the impurity-doped polysilicon layer. Particularly, the reinforcing pattern 120 may be formed to have through-holes 122 partially exposing the frontside surface of the field isolation region 106.

After forming the gate electrode 114 and the reinforcing pattern 120, a spacer layer (not shown) may be formed on the frontside surface 102A of the substrate 102, and then an anisotropic etching process may be performed to form the gate spacer 116 on side surfaces of the gate electrode 114. Further, a second spacer 124 may be simultaneously formed on side surfaces of the reinforcing pattern 120 by the anisotropic etching process along with the gate spacer 116. The spacer layer may be formed of silicon oxide or silicon nitride, and in this case, the through-holes 122 of the reinforcing pattern 120 may be filled with the silicon oxide or silicon nitride.

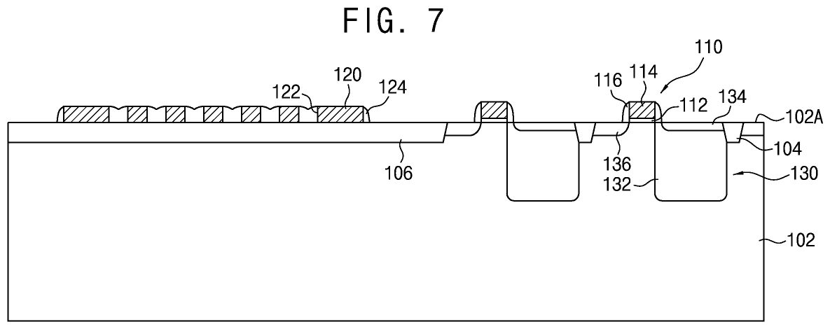

Referring to FIG. 7, charge accumulation regions 132 used as pixel regions 130 may be formed in the substrate 102. In detail, charge accumulation regions 132 having a second conductivity type may be formed in the active regions of the substrate 102. For example, n-type charge accumulation regions 132 may be formed in the p-type substrate 102. The n-type charge accumulation regions 132 may be n-type impurity diffusion regions formed by an ion implantation process.

Then, frontside pinning layers 134 having the first conductivity type may be formed between the frontside surface 102A of the substrate 102 and the charge accumulation regions 132. For example, p-type frontside pinning layers 134 may be formed between the frontside surface 102A of the substrate 102 and the n-type charge accumulation regions 132 by an ion implantation process. The p-type frontside pinning layers 134 may be p-type impurity diffusion regions. The n-type charge accumulation regions 132 and the p-type frontside pinning layers 134 may be activated by a subsequent rapid heat treatment process.

Further, floating diffusion regions 136 having the second conductivity type may be formed in frontside surface portions of the substrate 102 to be spaced apart from the charge accumulation regions 132. For example, the floating diffusion regions 136 may be n-type high concentration impurity regions, which may be formed by an ion implantation process. At this time, the transfer gate structures 110 may be arranged on channel regions between the charge accumulation regions 132 and the floating diffusion regions 136.

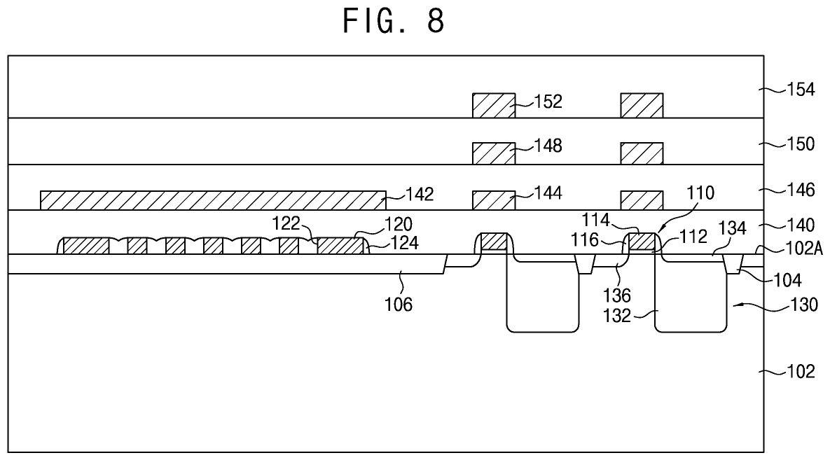

Referring to FIG. 8, an insulating layer 140 may be formed on the frontside surface 102A of the substrate 102, and a bonding pad 142 and a first wiring layer 144 may be formed on the insulating layer 140. The insulating layer 140 may be made of an insulating material such as silicon oxide, and the bonding pad 142 and the first wiring layer 144 may be made of a metallic material such as copper or aluminum. For example, after forming the insulating layer 140, a conductive layer (not shown) such as an aluminum layer may be formed on the insulating layer 140, and the bonding pad 142 and the first wiring layer 144 may then be formed by patterning the conductive layer. In this case, the bonding pad 142 may be formed to correspond to the reinforcing pattern 120.

Further, a second insulating layer 146 may be formed on the insulating layer 140, the bonding pad 142 and the first wiring layer 144, and a second wiring layer 148 may be formed on the second insulating layer 146. A third insulating layer 150 may be formed on the second insulating layer 146 and the second wiring layer 148, and a third wiring layer 152 may be formed on the third insulating layer 150. A passivation layer 154 may be formed on the third insulating layer 150 and the third wiring layer 152. The first, second and third wiring layers 144, 148 and 152 may be electrically connected with the pixel regions 130, and the bonding pad 142 may be electrically connected with the first, second and third wiring layers 144, 148 and 152.

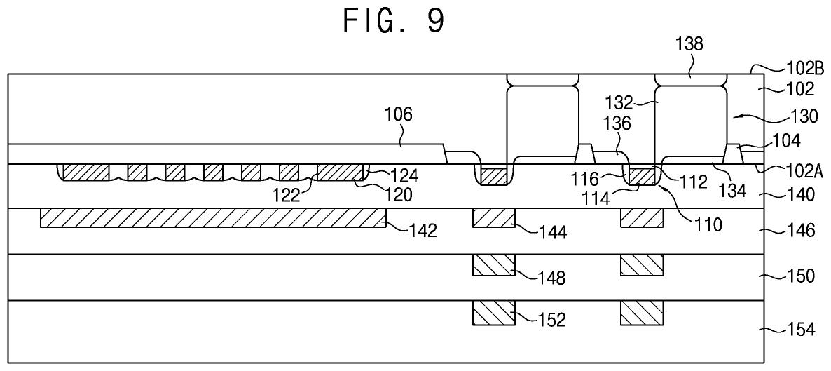

Referring to FIG. 9, a back-grinding process or a chemical and mechanical polishing process may be performed in order to reduce a thickness of the substrate 102. Further, backside pinning layers 138 having the first conductivity type may be formed between a backside surface 102B of the substrate 102 and the charge accumulation regions 132. For example, p-type impurity regions functioning as the backside pinning layers 138 may be formed by an ion implantation process, and may then be activated by a subsequent laser annealing process.

Alternatively, the backside pinning layers 138 may be formed prior to the charge accumulation regions 132. For example, after forming the backside pinning layers 138, the charge accumulation regions 132 may be formed on the backside pinning layers 138, and the frontside pinning layers 134 may then be formed on the charge accumulation regions 132. In such case, the backside pinning layers 138 may be activated by the rapid heat treatment process along with the charge accumulation regions 132 and the frontside pinning layers 134. Further, the back-grinding process may be performed such that the backside pinning layers 138 are exposed.

Meanwhile, when the substrate 102 includes a bulk silicon substrate and a p-type epitaxial layer formed on the bulk silicon substrate, the charge accumulation regions 132 and the frontside and backside pinning layers 134 and 138 may be formed in the p-type epitaxial layer, and the bulk silicon substrate may be removed by the back-grinding process.

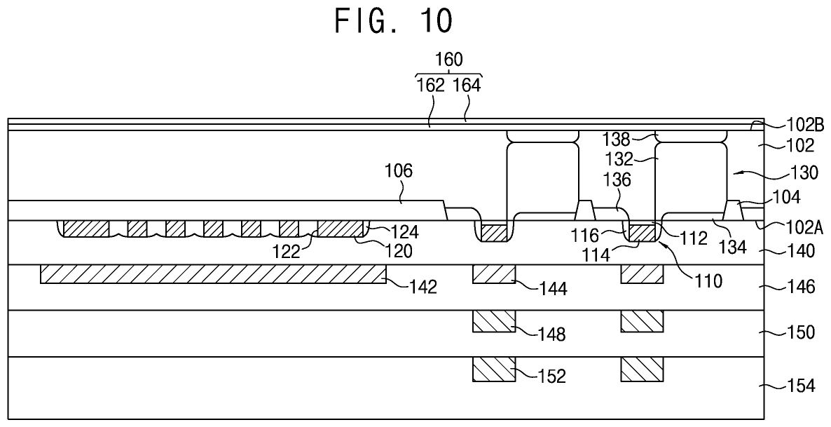

Referring to FIG. 10, an anti-reflective layer 160 may be formed on the backside surface 102B of the substrate 102. For example, a metal oxide layer 162 may be formed on the backside surface 102B of the substrate 102, and then a silicon oxide layer 164 may be formed on the metal oxide layer 162. Although not shown in detail, the metal oxide layer 162 may include an aluminum oxide layer formed on the backside surface 102B of the substrate 102 and a hafnium oxide layer formed on the aluminum oxide layer.

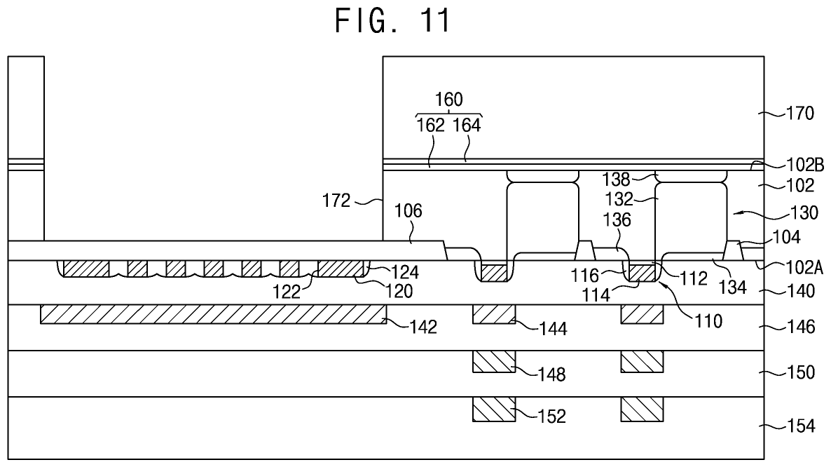

Referring to FIG. 11, a first photoresist pattern 170 may be formed on the anti-reflective layer 160, and an anisotropic etching process using the first photoresist pattern 170 as an etch mask may be performed to form a first opening 172 partially exposing a backside surface of the field isolation region 106. That is, the first opening 172 may be formed through the anti-reflective layer 160 and the substrate 102. The first photoresist pattern 170 may be removed through an ashing and/or stripping process after the first opening 172 is formed.

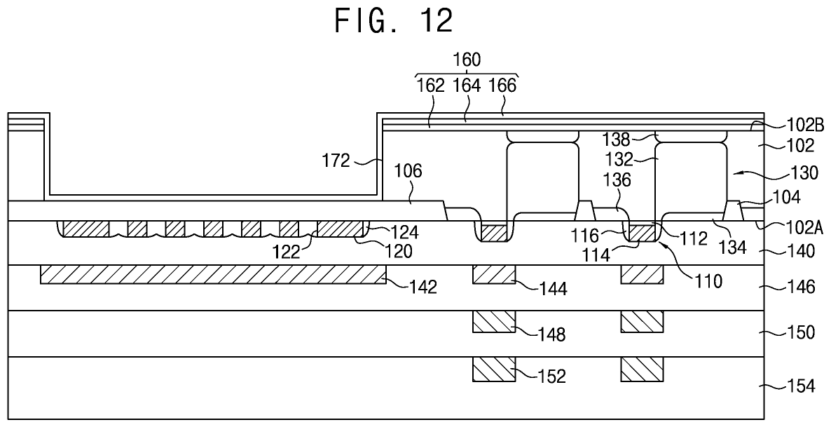

Referring to FIG. 12, A second silicon oxide layer 166 may be formed on the silicon oxide layer 164, inner side surfaces of the first opening 172, and a portion of the field isolation region 106 exposed by the first opening 172. The second silicon oxide layer 166 may be formed to electrically insulate the substrate 102 and a second bonding pad 188 to be formed subsequently, and may function as a part of the anti-reflective layer 160.

Alternatively, the first opening 172 may be formed after the metal oxide layer 162 is formed. Then, A silicon oxide layer (not shown) may be formed on the metal oxide layer 162, the inner side surfaces of the first opening 172, and the portion of the field isolation region 106 exposed by the first opening 172. In such case, the second silicon oxide layer 166 may be omitted.

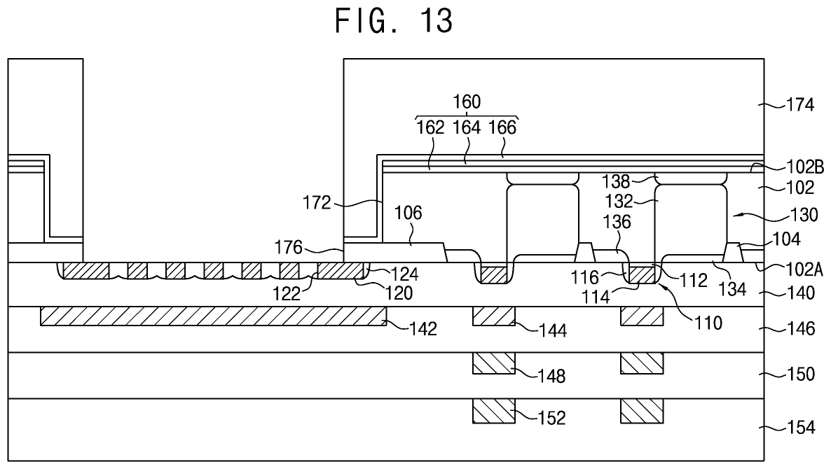

Referring to FIG. 13, a second opening 176 for partially exposing the reinforcing pattern 120 may be formed by partially removing the second silicon oxide layer 166 and the field isolation region 106. For example, after forming a second photoresist pattern 174 partially exposing the second silicon oxide layer 166, an anisotropic etching process using the second photoresist pattern 174 as an etch mask may be performed to form a second opening 176 for partially exposing the reinforcing pattern 120 through the second silicon oxide layer 166 and the field isolation region 106.

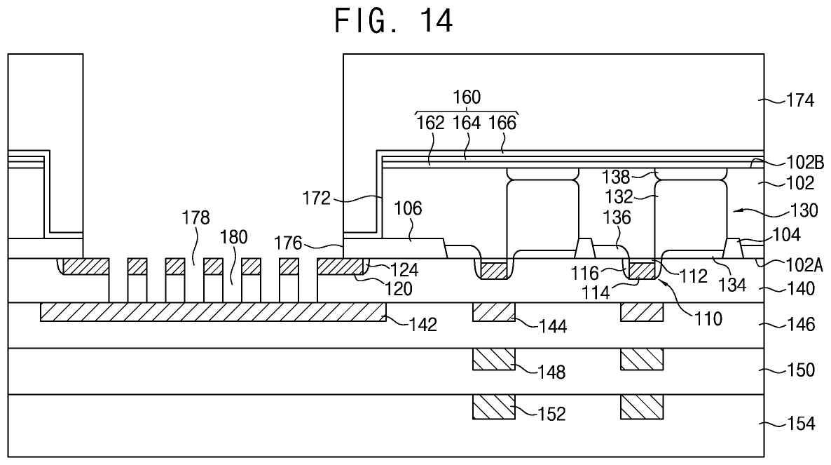

Referring to FIG. 14, third openings 178 penetrating through the reinforcing pattern 120 and fourth openings 180 penetrating through the insulating layer 140 may be formed by the anisotropic etching process, and thus, backside surface portions of the bonding pad 142 may be exposed by the third openings 178 and the fourth openings 180. In such case, the reinforcing pattern 120 may be used as an etch mask to form the third openings 178 and the fourth openings 180. That is, portions of the spacer layer in the through-holes 122 of the reinforcing pattern 120 may be removed by the anisotropic etching process, and thus, the third openings 178 penetrating through the reinforcing pattern 120 may be formed. Then, the insulating layer 140 may be partially removed, and thus, the fourth openings 180 penetrating through the insulating layer 140 may be formed. The second photoresist pattern 174 may be removed through an ashing and/or stripping process after the third openings 178 and the fourth openings 180 are formed.

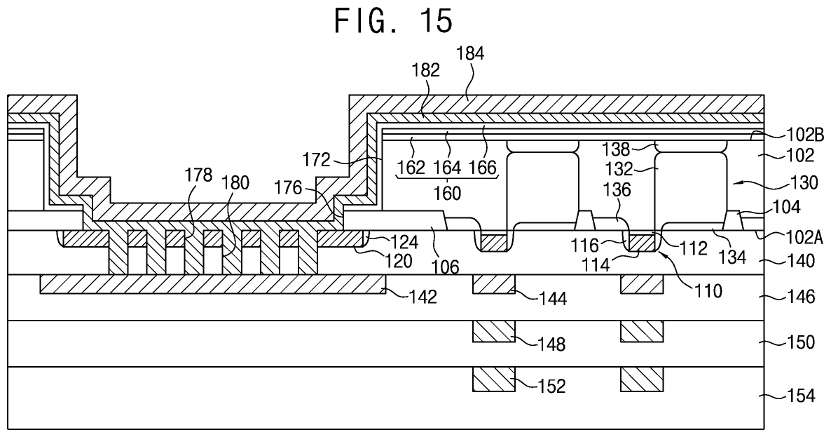

Referring to FIG. 15, a second conductive layer 182 such as a tungsten layer may be formed on the second silicon oxide layer 166, inner surfaces of the second opening 176, a portion of the reinforcing pattern 120 exposed by the second opening 176, inner surfaces of the third and fourth openings 178 and 180, and portions of the bonding pad 142 exposed by the third and fourth openings 178 and 180. Then, a third conductive layer 184 such as an aluminum layer may be formed on the second conductive layer 182. In this case, the second conductive layer 182 may be formed to fill the third and fourth openings 178 and 180. Alternatively, when the sizes of the third and fourth openings 178 and 180 are relatively large, the second conductive layer 182 may be formed along the inner surfaces of the third and fourth openings 178 and 180, and the third and fourth openings 178 and 180 may be filled by the third conductive layer 184.

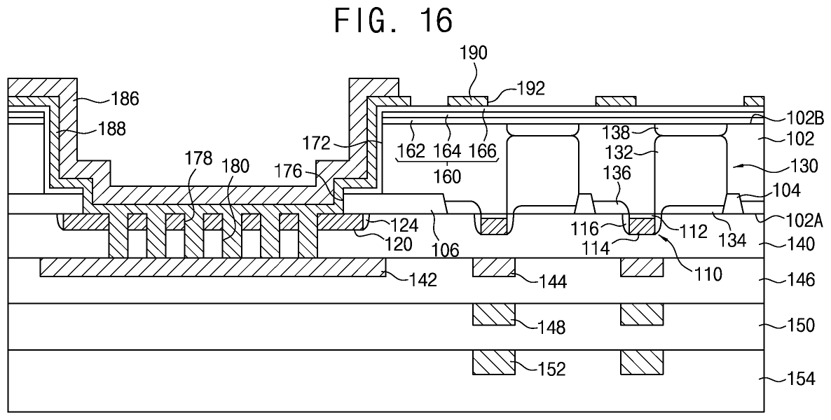

Referring to FIG. 16, a third bonding pad 186 may be formed on the second conductive layer 182 by patterning the third conductive layer 184. Then, by patterning the second conductive layer 182, a light-blocking pattern 190 having fifth openings 192 respectively corresponding to the pixel regions 130 may be formed on the anti-reflective layer 160, and a second bonding pad 188 electrically connecting the bonding pad 142 and the third bonding pad 186 may be formed.

Referring again to FIG. 1, a planarization layer 194 made of an insulating material such as silicon oxide or a thermosetting resin may be formed on the anti-reflective layer 160 and the light-blocking pattern 190, and a color filter layer 196 and a microlens array 198 may be sequentially formed on the planarization layer 194.

In accordance with the embodiments of the present disclosure as described above, the second bonding pad 188 may be electrically connected to the bonding pad 142 through the insulating layer 140 and the reinforcing pattern 120 formed on the frontside surface 102A of the substrate 102, and thus the second bonding pad 188 may be firmly supported by the reinforcing pattern 120. As a result, the problem that the second bonding pad 188 is peeled off from the bonding pad 142 may be sufficiently solved.

Although the example embodiments of the present disclosure have been described with reference to the specific embodiments, they are not limited thereto. Therefore, it will be readily understood by those skilled in the art that various modifications and changes can be made thereto without departing from the spirit and scope of the present disclosure defined by the appended claims.

What is claimed is:

1. A backside illuminated image sensor comprising:
a substrate having a frontside surface and a backside surface;
a pixel region disposed in the substrate;
a reinforcing pattern disposed on the frontside surface of the substrate;
an insulating layer disposed on the frontside surface of the substrate and the reinforcing pattern;
a bonding pad disposed on the insulating layer; and
a second bonding pad electrically connected to the bonding pad through the substrate, the reinforcing pattern, and the insulating layer.

2. The backside illuminated image sensor of claim 1, further comprising a field isolation region disposed in a frontside surface portion of the substrate,
wherein the reinforcing pattern is disposed on a frontside surface of the field isolation region, and the second bonding pad is electrically connected to the bonding pad through the field isolation region.

3. The backside illuminated image sensor of claim 2, wherein the substrate has a first opening exposing a backside surface of the field isolation region,
the field isolation region has a second opening exposing a backside surface of the reinforcing pattern,
the insulating layer has at least one fourth opening exposing a backside surface of the bonding pad, and
the reinforcing pattern has at least one third opening connecting the second opening and the at least one fourth opening.

4. The backside illuminated image sensor of claim 3, wherein the reinforcing pattern has a wider width than the second opening.

5. The backside illuminated image sensor of claim 3, wherein the reinforcing pattern has a plurality of third openings having a slit shape and extending parallel to each other.

6. The backside illuminated image sensor of claim 3, wherein the reinforcing pattern has a plurality of third openings arranged in rows and columns.

7. The backside illuminated image sensor of claim 1, further comprising at least one gate structure disposed on the frontside surface of the substrate.

8. The backside illuminated image sensor of claim 7, wherein the at least one gate structure comprises a gate insulating layer disposed on the frontside surface of the substrate, a gate electrode disposed on the gate insulating layer, and a gate spacer disposed on side surfaces of the gate electrode, and
the reinforcing pattern is made of a same material as the gate electrode.

9. The backside illuminated image sensor of claim 8, further comprising a second spacer disposed on side surfaces of the reinforcing pattern,
wherein the second spacer is made of a same material as the gate spacer.

10. The backside illuminated image sensor of claim 1, further comprising:
an anti-reflective layer disposed on the backside surface of the substrate; and
a light-blocking pattern disposed on the anti-reflective layer and having a fifth opening corresponding to the pixel region,
wherein the second bonding pad is made of a same material as the light-blocking pattern.

11. A method of manufacturing a backside illuminated image sensor, the method comprising:
forming a pixel region in a substrate;
forming a reinforcing pattern on a frontside surface of the substrate;
forming an insulating layer on the frontside surface of the substrate and the reinforcing pattern;
forming a bonding pad on the insulating layer; and
forming a second bonding pad to be electrically connected to the bonding pad through the substrate, the reinforcing pattern, and the insulating layer.

12. The method of claim 11, further comprising forming a field isolation region in a frontside surface portion of the substrate,
wherein the reinforcing pattern is formed on a frontside surface of the field isolation region, and the second bonding pad is electrically connected to the bonding pad through the field isolation region.

13. The method of claim 12, further comprising:
forming a first opening through the substrate to expose a backside surface of the field isolation region;
forming a second opening through the field isolation region to expose a backside surface of the reinforcing pattern; and
forming at least one third opening through the reinforcing pattern and at least one fourth opening through the insulating layer to expose a backside surface of the bonding pad.

14. The method of claim 13, wherein the second bonding pad is formed to fill the at least one third opening and the at least one fourth opening.

15. The method of claim 13, wherein the first opening partially exposes the backside surface of the field isolation region, and the second opening partially exposes the backside surface of the reinforcing pattern.

16. The method of claim 13, wherein the reinforcing pattern is formed on the frontside surface of the field isolation region to have at least one through-hole exposing a portion of the frontside surface of the field isolation region, and
the at least one third opening and the at least one fourth opening are formed by an anisotropic etching process using the reinforcing pattern as an etch mask.

17. The method of claim 11, further comprising forming at least one gate structure on the frontside surface of the substrate.

18. The method of claim 17, wherein the forming at least one gate structure comprises forming a gate insulating layer on the frontside surface of the substrate, forming a gate electrode on the gate insulating layer, and forming a gate spacer on side surfaces of the gate electrode, and
the reinforcing pattern is formed simultaneously with the gate electrode.

19. The method of claim 18, further comprising forming a second spacer on side surfaces of the reinforcing pattern,
wherein the second spacer is formed simultaneously with the gate spacer.

20. The method of claim 11, further comprising:
forming an anti-reflective layer on the backside surface of the substrate; and
forming a light-blocking pattern having a fifth opening corresponding to the pixel region on the anti-reflective layer,
wherein the second bonding pad is formed simultaneously with the light-blocking pattern.
